(19) United States
(12) Patent Application Publication
(10) Pub. No.: US 2025/0221154 A1
(43) Pub. Date: Jul. 3, 2025

(54) DISPLAY APPARATUS HAVING A LIGHT-EMITTING DEVICE

(71) Applicant: LG Display Co., Ltd., Seoul (KR)

(72) Inventors: Hwa Yong SHIN, Paju-si (KR); Jae Young KWAK, Paju-si (KR); Hyeok Soo JANG, Paju-si (KR)

(73) Assignee: LG Display Co., Ltd., Seoul (KR)

(21) Appl. No.: 18/783,120

(22) Filed: Jul. 24, 2024

(30) Foreign Application Priority Data
Dec. 29, 2023 (KR) 10-2023-0197870

(51) Int. Cl. H10K 50/15; G09G 3/3233; H10K 50/19; H10K 59/35

(52) U.S. Cl. CPC H10K 50/156; H10K 50/19; G09G 3/3233; G09G 2300/0426; G09G 2300/0842; H10K 59/35

(57) ABSTRACT

Discussed is display apparatus in which a light-emitting device includes a charge generation layer and at least one hole transport layer is provided. The hole transport layer and/or the charge generation layer of each pixel area can be spaced apart from the hole transport layer and/or the charge generation layer of adjacent pixel area. The hole transport layer and/or the charge generation layer on the pixel area displaying a blue color can include a content of p-type dopant lower than the hole transport layer and/or the charge generation layer on the pixel region that displays a color other than blue. Thus, in the display apparatus, a leakage current between the pixel areas can be minimized. Therefore, in the display apparatus, efficiency of each pixel area can be improved.

### CROSS-REFERENCE TO RELATED APPLICATIONS

This application claims priority to Korean Patent Application No. 10-2023-0197870, filed in the Republic of Korea on Dec. 29, 2023, the entire contents of which is hereby expressly incorporated by reference into the present application.

### BACKGROUND

### Field

The present disclosure relates to a display apparatus in which a light-emitting device includes a charge generation layer and at least one hole transport layer.

### Discussion of the Related Art

Generally, a display apparatus is used in providing an image to a user. For example, the display apparatus can include light-emitting devices on pixel areas which are utilized to provide the image. Each of the light-emitting devices can emit light displaying a specific color of a pixel on the pixel areas. Also, each of the light-emitting devices can include a light-emitting unit between a lower electrode and an upper electrode, and the light-emitting unit can include a plurality of emission material layers that generate light of the specific color. For example, the light-emitting unit can include a charge generation layer and at least one hole transport layer that can handle a hole that can be used in generating the light of the specific color.

The image provided to the user can include a plurality of colors. For example, each of the pixel areas can be one of a red pixel area displaying a red color, a green pixel area displaying a green color and a blue pixel area displaying a blue color. The light-emitting unit of each pixel area can be partially connected to the light-emitting unit of an adjacent pixel area. When the light emitting units are partially connected, the hole transport layer and the charge generation layer of one pixel area can be in direct contact with the hole transport layer and the charge generation layer of an adjacent pixel area. Thus, in the display apparatus, a driving current applied to the light-emitting device of the one pixel area can leak in to the light-emitting device of the adjacent pixel area through the hole transport layer and/or the charge generation layer. Thus, in the display apparatus having the light emitting units that are partially connected, light can be generated and emitted in unintended area due to a leakage current between the pixel areas.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of preventing or reducing the generation and the emission of light in unintended areas of the display apparatus.

Another object of the present disclosure is to provide a display apparatus in which a driving current applied to the light-emitting device of each emission area may not be leaked to an outside of a corresponding emission area.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus including a device substrate. The device substrate includes a first pixel area and a second pixel area. The first pixel area displays a blue color. The second pixel area displays a different color from the first pixel area. A first light-emitting device is disposed on the first pixel area. The first light-emitting device has a stacked structure of a first lower electrode, a first lower hole transport layer, a first lower emission material layer, a first charge generation layer, a first upper emission material layer and a first upper electrode. A second light-emitting device is disposed on the second pixel area. The second light-emitting device has a stacked structure of a second lower electrode, a second lower hole transport layer, a second lower emission material layer, a second charge generation layer, a second upper emission material layer and a second upper electrode. The second lower hole transport layer is spaced apart from the first lower hole transport layer. The content of p-type dopant in the first lower hole transport layer is smaller than the content of p-type dopant in the second lower hole transport layer.

The p-type dopant in the second lower hole transport layer can include a same material as the p-type dopant in the first lower hole transport layer.

The first light-emitting device can include a first upper hole transport layer disposed between the first charge generation layer and the first upper emission material layer. The second light-emitting device can include a second upper hole transport layer disposed between the second charge generation layer and the second upper emission material layer. The second upper hole transport layer can be spaced apart from the first upper hole transport layer.

The content of p-type dopant in the first upper hole transport layer can be smaller than the content of p-type dopant in the second upper hole transport layer.

A third light-emitting device can be disposed on a third pixel area of the device substrate. The third light-emitting device can have a stacked structure of a third lower electrode, a third lower hole transport layer, a third lower emission material layer, a third charge generation layer, a third upper emission material layer and a third upper electrode. The third pixel area can display a different color from the first pixel area and the second pixel area. The third lower hole transport layer can be spaced apart from the first lower hole transport layer and the second lower hole transport layer. The content of p-type dopant in the third lower hole transport layer can be greater than the content of p-type dopant in the first lower hole transport layer.

The second pixel area can display a green color. The third pixel area can display a red color. The content of p-type dopant in the third lower hole transport layer can be greater than the content of p-type dopant in the second lower hole transport layer.

The second lower emission material layer can be spaced apart from the first lower emission material layer. The second upper emission material layer can be spaced apart from the first lower emission material layer. Light emitted from the first upper emission material layer can display a same color as the light emitted from the first lower emission material layer. Light emitted from the second upper emission material layer can display a same color as the light emitted from the second lower emission material layer.

Each of the first charge generation layer and the second charge generation layer can have a stacked structure of an n-type charge generating layer and a p-type charge generating layer. The p-type charge generating layer of the second charge generation layer can be spaced apart from the p-type charge generating layer of the first charge generation layer.

In another aspect of the present disclosure, there is provided a display apparatus comprising a device substrate. A first lower electrode is disposed on a first emission area of the device substrate. A second lower electrode is disposed on a second emission area of the device substrate. A light-emitting unit is disposed on the first lower electrode and the second lower electrode. The light-emitting unit has a stacked structure of a first emission material layer, a charge generation layer and a second emission material layer. An upper electrode is disposed on the light-emitting unit. The upper electrode overlaps the first emission area and the second emission area. The charge generation layer of the light-emitting unit has a stacked structure of an n-type charge generating layer and a p-type charge generating layer. The p-type charge generating layer overlapping with the second emission area is spaced apart from the p-type charge generating layer overlapping with the first emission area. The content of p-type dopant in the p-type charge generating layer on the second emission area is different from the content of p-type dopant in the p-type charge generating layer on the first emission area.

The p-type dopant in the p-type charge generating layer on the second emission area can include a same material as the p-type dopant in the p-type charge generating layer on the first emission area.

The light-emitting unit can include an upper hole transport layer disposed between the charge generation layer and the second emission material layer. The upper hole transport layer overlapping with the second emission area can be spaced apart from the upper hole transport layer overlapping with the first emission area. The content of p-type dopant in the upper hole transport layer on the second emission area can be different from the content of p-type dopant in the upper hole transport layer on the first emission area.

The content of p-type dopant in the p-type charge generating layer on the first emission area can be smaller than the content of p-type dopant in the p-type charge generating layer on the second emission area. The content of p-type dopant in the upper hole transport layer on the first emission area can be smaller than the content of p-type dopant in the upper hole transport layer on the second emission area.

A third lower electrode can be disposed on a third emission area of the device substrate. The light-emitting unit and the upper electrode can extend onto the third lower electrode. The p-type charge generating layer overlapping with the third emission area can be spaced apart from the p-type charge generating layer overlapping with the first emission area and the p-type charge generating layer overlapping with the second emission area. The content of p-type dopant in the p-type charge generating layer on the third emission area can be different from the content of p-type dopant in the p-type charge generating layer on the first emission area.

The content of p-type dopant in the p-type charge generating layer on the third emission area can be different from the content of p-type dopant in the p-type charge generating layer on the second emission area.

A first color filter can be disposed between the first emission area of the device substrate and the first lower electrode. A second color filter can be disposed between the second emission area of the device substrate and the second lower electrode. Each of the first emission material layer and the second emission material layer in the light-emitting unit can overlap the first emission area and the second emission area. The second color filter can include a different material from the first color filter.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing an example of a circuit of a pixel area in the display apparatus according to the embodiment of the present disclosure;

FIG. 3 is a view schematically showing a cross-section of the pixel areas in the display apparatus according to the embodiment of the present disclosure;

FIG. 4 is an enlarged view of a K1 region and a K2 region in FIG. 3; and

FIGS. 5 to 9 are views showing a display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### EMBODIMENTS

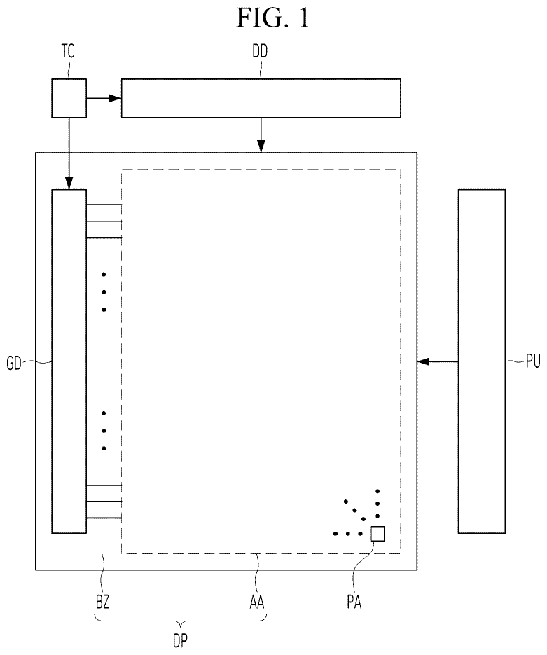

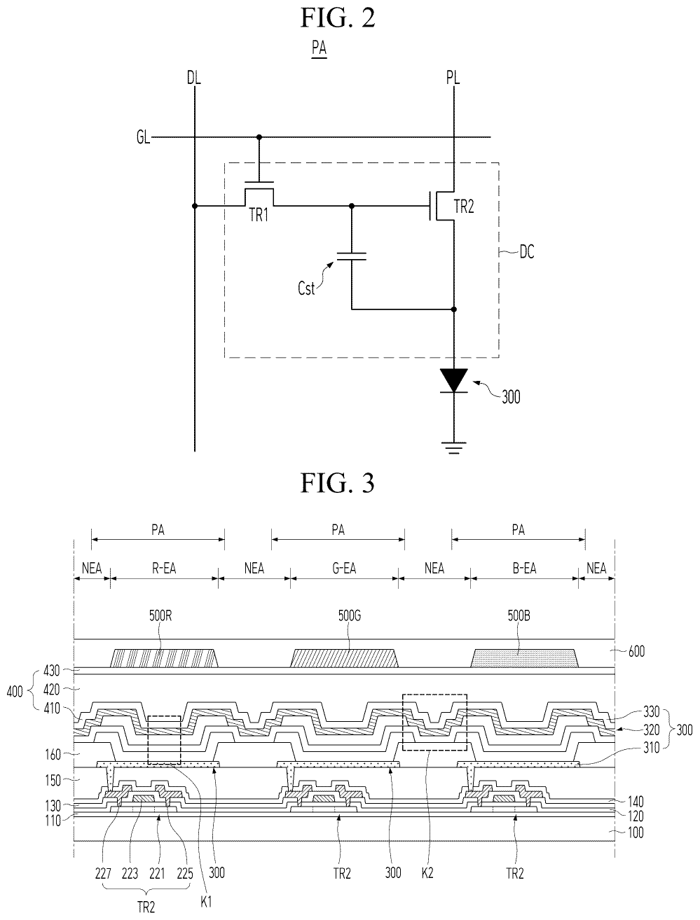

FIG. 1 is a view schematically showing a display apparatus according to an embodiment of the present disclosure. FIG. 2 is a view showing an example of a circuit of a pixel area in the display apparatus according to the embodiment of the present disclosure. All the components of the display apparatus according to all embodiments are operationally coupled and configured.

Referring to FIGS. 1 and 2, the display apparatus according to the embodiment of the present disclosure can include a display panel DP. The display panel DP can generate an image provided to a user. For example, a plurality of pixel areas PA can be disposed in the display panel DP. Various signals can be provided in each pixel area PA through signal wirings GL, DL and PL. For example, the signal wirings GL, DL and PL can include gate lines GL for applying a gate signal, data lines DL for applying a data signal, and power voltage supply lines PL for supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC.

The display panel DP can include an active area (or display area) AA in which the pixel areas PA are disposed, and a bezel area BZ (or non-display area) disposed outside the active area AA. The pixel areas PA can be disposed in a region defined by the bezel area BZ. For example, the active area AA can be surrounded by the bezel area BZ. The gate driver GD, the data driver DD, the power unit PU and the timing controller TC can be disposed outside the active area AA. For example, each of the signal wiring GL, DL and PL can include a portion overlapping with the bezel area BZ.

At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color. For example, a driving circuit DC electrically connected to a light-emitting device 300 can be disposed in each pixel area PA. The driving circuit DC of each pixel area PA can control the light-emitting device 300 of the corresponding pixel area PA according to signals applied through the signal wirings GL, DL and PL. For example, the driving circuit DC of each pixel area PA can be electrically connected to the signal wirings GL, DL and PL. For example, the driving circuit DC of each pixel area PA can be electrically connected to one of the gate lines GL, one of the data lines DL, and one of the power voltage supply lines PL. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst. In various embodiments of the present disclosure, the display apparatus can include additional elements that are used to provide an image.

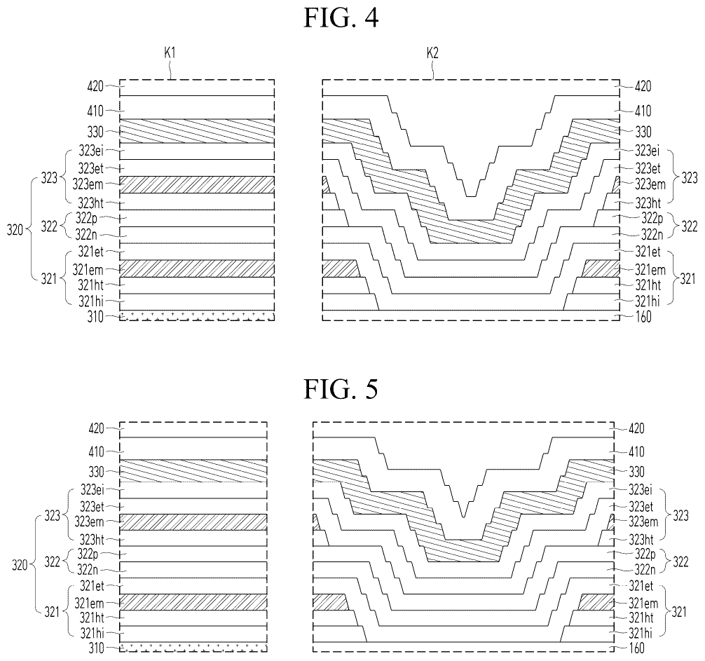

FIG. 3 is a view schematically showing a cross-section of the pixel areas in the display apparatus according to the embodiment of the present disclosure.

Referring to FIGS. 2 and 3, the first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The first semiconductor pattern can include a semiconductor material. For example, the first semiconductor pattern can include amorphous silicon (a-Si), polycrystalline silicon (poly-Si) or an oxide semiconductor, such as IGZO. But embodiments of the present disclosure are not limited thereto. The first semiconductor pattern can include a first drain region, a first channel region and a first source region. The first channel region can be disposed between the first drain region and the first source region. The first drain region and the first source region can have a smaller resistance than the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The first drain electrode can include a different material from the first gate electrode. The first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the corresponding power voltage supply line PL.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. But embodiments of the present disclosure are not limited thereto. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a smaller resistance than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The second drain electrode 225 can include a different material from the second gate electrode 223. The second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). But embodiments of the present disclosure are not limited thereto, and other conductive materials can be used, including non-metals. The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a signal applied to the second gate electrode 223 of the corresponding pixel area PA for one frame. For example, the storage capacitor Cst of each pixel area PA can be electrically connected between the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel area PA.

The storage capacitor Cst of each pixel area PA can be formed by using a process of forming the first thin film transistor TR1 and the second thin film transistor TR2 of the corresponding pixel area PA. For example, the first capacitor electrode of each pixel area PA can be disposed on a same layer as the second gate electrode 223 of the corresponding pixel area PA, and the second capacitor electrode of each pixel area PA can be disposed on a same layer as the second source electrode 227 of the corresponding pixel area PA. The first capacitor electrode of each pixel area PA can include a same material as the second gate electrode 223 of the corresponding pixel area PA, and the second capacitor electrode of each pixel area PA can include a same material as the second source electrode 227 of the corresponding pixel area PA. The first capacitor of each pixel area PA can be formed by a same process as the second gate electrode 223 of the corresponding pixel area PA, and the second capacitor electrode of each pixel area PA can be formed by a same process as the second source electrode 227 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA.

The driving circuit DC and the light-emitting device 300 of each pixel area PA can be supported by a device substrate 100. For example, the first thin film transistor TR1, the second thin film transistor TR2 and the storage capacitor Cst of each pixel area PA can be disposed on the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed close to the device substrate 100. The buffer insulating layer 110 can prevent pollution or contamination due to the device substrate 100 in a process of forming the driving circuit DC of each pixel area PA. For example, an upper surface of the device substrate 100 toward the driving circuit DC of each pixel area PA can be completely covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). But embodiments of the present disclosure are not limited thereto, and other non-organic materials can be used, or alternatively, organic insulating materials can be used. The buffer insulating layer 110 can have a multi-layer structure, but such is not required. For example, the buffer insulating layer 110 can have a structure in which an inorganic insulating layer made of silicon oxide (SiOx) and an inorganic insulating layer made of silicon nitride (SiNx) are stacked, but can be a single layer as well.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx). But embodiments of the present disclosure are not limited thereto, and other non-organic materials can be used, or alternatively, organic insulating materials can be used.

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrodes 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent damage of the driving circuit DC in each pixel area PA due to external impact and moisture. The device passivation layer 140 can extend along an upper surface of the driving circuit DC in each pixel area PA opposite to the device substrate 100. For example, the first drain electrode, the first source electrode, the second drain electrode 225 and the second source electrode 227 of each pixel area PA can be covered by the device passivation layer 140. The first drain electrode of each pixel area PA can be in direct contact with the first drain region of the corresponding pixel area PA by penetrating the gate insulating layer 120 and the interlayer insulating layer 130, and the first source electrode of each pixel area PA can be in direct contact with the first source region of the corresponding pixel area PA by penetrating the gate insulating layer 120 and the interlayer insulating layer 130. The second drain electrode 225 of each pixel area PA can be in direct contact with the second drain region of the corresponding pixel area PA by penetrating the gate insulating layer 120 and the interlayer insulating layer 130, and the second source electrode 227 of each pixel area PA can be in direct contact with the second source region of the corresponding pixel area PA by penetrating the gate insulating layer 120 and the interlayer insulating layer 130. The device passivation layer 140 can include an insulating material. For example, the device passivation layer 140 can be an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be a flat surface or be made a flat surface. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the planarization layer 150. The light-emitting device 300 of each pixel area PA can emit light displaying a specific color. For example, the light-emitting device 300 of each pixel area PA can include a lower electrode 310, a light-emitting unit 320 and an upper electrode 330, which are sequentially stacked on the planarization layer 150 of the corresponding pixel area PA.

The light-emitting unit 320 can generate light having luminance corresponding to a voltage difference between the lower electrode 310 and the upper electrode 330. For example, the light-emitting unit 320 can include an emission material layer (EML). The emission material layer can include an organic emission material, an inorganic emission material or a hybrid emission material. For example, the display apparatus according to the embodiment of the present disclosure can be an organic light-emitting display apparatus in which the light-emitting unit 320 includes an organic emission material.

The lower electrode 310 and the upper electrode 330 can include a conductive material. The upper electrode 330 can include a different material from the lower electrode 310. A reflectance of the lower electrode 310 can be higher than a reflectance of the upper electrode 330. The upper electrode 330 can include a material having a higher transmittance than the lower electrode 310. For example, the lower electrode 310 can include a metal, such as aluminum (Al) and silver (Ag), and the upper electrode 330 can be a transparent electrode made of a transparent conductive material, such as ITO and IZO. But embodiments of the present disclosure are not limited thereto. The lower electrode 310 can have a multi-layer structure, but can also be a single layer. For example, the lower electrode 310 can have a structure in which a reflective electrode made of a metal is disposed between transparent electrodes made of a transparent conductive material, such as ITO and IZO. Thus, in the display apparatus according to the embodiment of the present disclosure, the light generated by the light-emitting unit 320 of each pixel area PA can be emitted outside through the upper electrode 330 of the corresponding pixel area PA.

The bank insulating layer 160 can be disposed on the planarization layer 150. The bank insulating layer 160 can define an emission area R-EA, G-EA and B-EA in each pixel area PA. A region between the emission areas R-EA, G-EA and B-EA can be defined by a non-emission area NEA. For example, the bank insulating layer 160 can overlap the non-emission area NEA of the device substrate 100. A portion of the lower electrode 310 in each pixel area PA can be exposed by the bank insulating layer 160. For example, the bank insulating layer 160 can cover an edge of the lower electrode 310 in each pixel area PA. The bank insulating layer 160 can include an insulating material. For example, the bank insulating layer 160 can be an organic insulating material. The bank insulating layer 160 can include a different material from the planarization layer 150. The lower electrode 310 of each pixel area PA can be insulated from the lower electrode 310 of adjacent pixel area PA by the bank insulating layer 160.

The lower electrode 310 of each pixel area PA can be electrically connected to the second thin film transistor TR2 of the driving circuit DC disposed in the corresponding pixel area PA. For example, the lower electrode 310 of each pixel area PA can be in direct contact with the second source electrode 227 of the corresponding pixel area PA by penetrating the device passivation layer 140 and the planarization layer 150. The second source electrode 227 and the lower electrode 310 of each pixel area PA can be electrically connected in the non-emission area NEA of the corresponding pixel area PA. For example, a portion of the lower electrode 310 in the emission area R-EA, G-EA and R-EA of each pixel area PA can be in direct contact with the upper surface of the planarization layer 150. The light-emitting unit 320 and the upper electrode 330 of each pixel area PA can be stacked on the portion of the corresponding lower electrode 310 exposed by the bank insulating layer 160. For example, in the display apparatus according to the embodiment of the present disclosure, the light-emitting unit 320 and the upper electrode 330 of each pixel area PA can be stacked on the portion of the lower electrode 310 overlapping with the emission area R-EA, G-EA and B-EA in the corresponding pixel area PA. Thus, in the display apparatus according to the embodiment of the present disclosure, a luminance deviation depending on the generation position of the light emitted from each pixel area PA can be prevented.

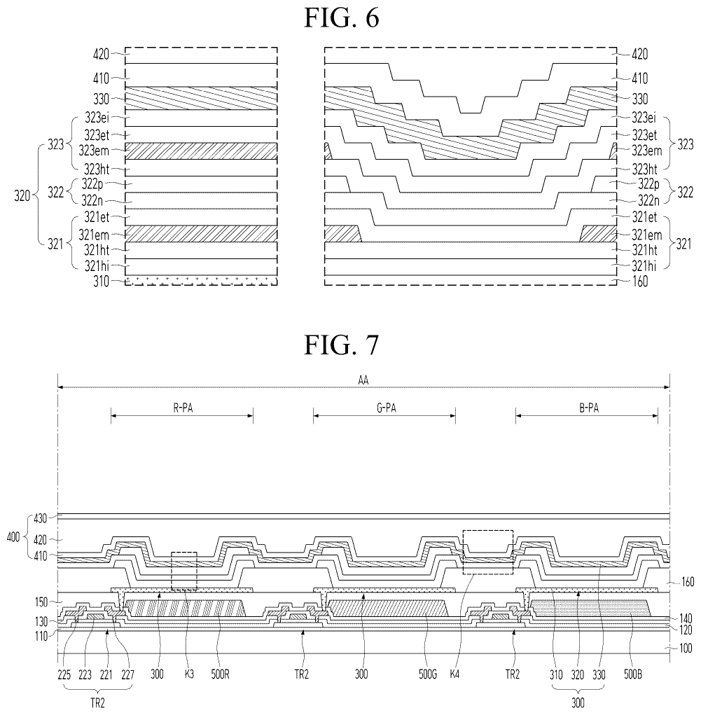

A plurality of emission material layer (EML) can be disposed in the light-emitting unit 320 of each pixel area PA. For example, the light-emitting unit 320 of each pixel area PA can include a first emission stack 321, a charge generation layer 322 and a second emission stack 323, which are sequentially stacked, as shown in FIGS. 3 and 4. Each of the first emission stack 321 and the second emission stack 323 can include at least one emission material layer (EML). The charge generation layer 322 can supply electrons or holes to the first emission stack 321 and the second emission tack 323. For example, the charge generation layer 322 can have a stacked structure of an n-type charge generating layer 322n and a p-type charge generating layer 322p. Each of the first emission stack 321 and the second emission stack 323 can emit light.

Each of the first emission stack 321 and the second emission stack 323 can include at least one functional layer to smoothly supply holes or electrons. The functional layer can be at least one of a hole injection layer (HIL), a hole transport layer (HTL), an electron transport layer (ETL) and an electron injection layer (EIL). For example, the first emission stack 321 can include a hole injection layer 321hi, a first hole transport layer 321ht, a first emission material layer 321em and a first electron transport layer 32let, and the second emission stack 323 can include a second hole transport layer 323ht, a second emission material layer 323em, a second electron transport layer 323et and an electron injection layer 323ei. The lower electrode 310 can function as an anode electrode, and the upper electrode 330 can function as a cathode electrode. For example, a work-function of the lower electrode 310 can be higher than a work-function of the upper electrode 330. The p-type charge generating layer 322p of the charge generation layer 322 can be disposed between the n-type charge generating layer 322n of the charge generation layer 322 and the second hole transport layer 323ht of the second emission stack 323.

Light generated by the second emission stack 323 can display a same color as light generated by the first emission stack 321. For example, the second emission material layer 323em of the second emission stack 323 can include a same material as the first emission material layer 321em of the first emission stack 321. The second emission material layer 323em of the second emission stack 323 can include a same material as the first emission material layer 321em of the first emission stack 321. The wavelength range of the light generated by the second emission stack 323 can be a same as the wavelength range of the light generated by the first emission stack 321. Thus, in the display apparatus according to the embodiment of the present disclosure, the color reproducibility of the light emitted from each pixel area PA can be improved.

In various embodiments of the present disclosure, the second hole transport layer 323ht of the second emission stack 322 can have a thickness different from the first hole transport layer 321ht of the first emission stack 321. For example, the second hole transport layer 323ht of the second emission stack 322 can have the thickness greater than the thickness of the first hole transport layer 321ht of the first emission stack 321, but embodiments of the present disclosure are not limited thereto.

The image provided to the user can include a plurality of colors. The light emitted from the emission area R-EA, G-EA and B-EA of each pixel area PA can display a different color from the light emitted from the emission area R-EA, G-EA and B-EA of adjacent pixel area PA. For example, the emission area R-EA, G-EA and B-EA of each pixel area PA can be one of a red emission area R-EA of a red pixel area in which the light displaying a red color is emitted, a green emission area G-EA of a green pixel area in which the light displaying a green color is emitted, and a blue emission area B-EA of a blue pixel area in which the light displaying a blue color is emitted. The first emission material layer 321em of each emission area R-EA, G-EA and B-EA can be separated from the first emission material layer 321em of adjacent emission area R-EA, G-EA and B-EA on the non-emission area NEA, and the second emission material layer 323em of each emission area R-EA, G-EA and B-EA can be separated from the second emission material layer 323em of adjacent emission area R-EA, G-EA and B-EA on the non-emission area NEA. In various embodiments of the present disclosure, the plurality of colors need not be limited to red, green and blue colors, but can be other colors, including such as white, yellow, magenta, cyan and others.

At least a portion of the hole injection layer 321hi, the first hole transport layer 321ht, the p-type charge generating layer 322p, and the second hole transport layer 323ht of each emission area R-EA, G-EA and B-EA can be doped with a p-type dopant. Here, the term ‘doped’ means that a second material having physical properties different from a first material was added to a layer in which the first material occupies most of the weight ratio. The hole injection layer 321hi, the first hole transport layer 321ht, the p-type charge generating layer 322p and the second hole transport layer 323ht of each emission area R-EA, G-EA and B-EA can include p-type dopants having a weight ratio of less than 30% of the corresponding layer. Thus, in the display apparatus according to the embodiment of the present disclosure, injection efficiency of holes into the first emission material layer 321em and/or the second emission material layer 323em of each emission area R-EA, G-EA and BEA through the hole injection layer 321hi, the first hole transport layer 321ht, the p-type charge generating layer 322p and the second hole transport layer 323ht of the corresponding emission area R-EA, G-EA and B-EA can be improved.

Various materials can be used as the p-type dopant. For example, at least a portion of the hole injection layer 321hi, the first hole transport layer 321ht, the p-type charge generating layer 322p, and the second hole transport layer 323ht of each emission area R-EA, G-EA and B-EA can be doped with boron. The p-type charge generating layer 322p of each emission area R-EA, G-EA and B-EA can consist of a p-type charge generating material including an inorganic material selected from the group consisting of tungsten oxide (WOx), molybdenum oxide (MoOx), beryllium oxide (Be2O3), vanadium oxide (V2O5) and combinations thereof, and an organic material selected from the group consisting of NPD, HAT-CN, F4TCNQ, TPD, TNB, TCTA, N,N′-diotyl-3,4,9,10-perylenedicarboximide (PTCDI-C8), an indacene derivative and combinations thereof. For example, the indacene derivative can include at least one of an indacene cyanide derivative and an indacene halide derivative, but embodiments of the disclosure are not limited thereto.

The hole injection layer 321hi, the first hole transport layer 321ht, the p-type charge generating layer 322p, and the second hole transport layer 323ht of each emission area R-EA, G-EA and B-EA can be respectively spaced apart from the hole injection layer 321hi, the first hole transport layer 321ht, the p-type charge generating layer 322p, and the second hole transport layer 323ht of adjacent emission area R-EA, G-EA and B-EA on the non-emission area NEA. For example, the hole injection layer 321hi of each emission area R-EA, G-EA and B-EA can be spaced apart from the hole injection layer 321hi of adjacent emission area R-EA, G-EA and B-EA, the first hole transport layer 321ht of each emission area R-EA, G-EA and B-EA can be spaced apart from the first hole transport layer 321ht of adjacent emission area R-EA, G-EA and B-EA, and the second hole transport layer 323ht of each emission area R-EA, G-EA and B-EA can be spaced apart from the second hole transport layer 323ht of adjacent emission area R-EA, G-EA and B-EA. The p-type charge generating layer 322p of each emission area R-EA, G-EA and B-EA can be spaced apart from the p-type charge generating layer 322p of adjacent emission area R-EA, G-EA and B-EA. Thus, in the display apparatus according to the embodiment of the present disclosure, a leakage current through the hole injection layer 321hi, the first hole transport layer 321ht, the p-type charge generating layer 322p, and the second hole transport layer 323ht of each emission area R-EA, G-EA and B-EA can be prevented.

Table 1 shows a threshold voltage difference (A Vth) and a relative leakage current (% Au′v′) between adjacent emission areas R-EA, G-EA and B-EA according to the content of p-type dopant doped into the first hole transport layer 321ht of the red emission area R-EA, the green emission area G-EA, and the blue emission area B-EA in the display apparatus according to the embodiment of the present disclosure. Here, the p-type dopant doped into the first hole transport layer 321ht of the red emission area R-EA, the green emission area G-EA, and the blue emission area B-EA can include a same material. Further, ΔVth(G-R) means a value obtained by subtracting the threshold voltage of the red emission area R-EA from the threshold voltage of the green emission area G-EA, and ΔVth(B-G) means a value obtained by subtracting the threshold voltage of the green emission area G-EA from the threshold voltage of the blue emission area B-EA.

TABLE 1

| | | | | ΔVth | ΔVth | Leakage current |
|---|---|---|---|---|---|---|
| | R-EA | G-EA | B-EA | (G-R) | (B-G) | (% Δu'v') |
| Comparative | 3% | 3% | 3% | 0.06 | 0.64 | 100% |
| example 1 | | | | | | |
| Comparative | 2% | 3% | 3% | 0.07 | 0.64 | 100% |
| example 2 | | | | | | |
| Comparative | 3% | 2% | 3% | 0.06 | 0.64 | 100% |
| example 3 | | | | | | |
| Experimental | 3% | 3% | 2% | 0.06 | 0.68 | 91% |
| example 1 | | | | | | |
| Experimental | 3% | 2% | 1% | 0.05 | 0.69 | 84% |
| example 2 | | | | | | |

Referring to Table 1, if the content of p-type dopant doped into the first hole transport layer 321ht of the blue emission area B-EA is relatively low, the leakage current can be reduced. Thus, in the display apparatus according to the embodiment of the present disclosure, the first hole transport layer 321ht of the blue emission area B-EA can include a p-type dopant having the content lower than the first hole transport layer 321ht of the red emission area R-EA and the first hole transport layer 321ht of the green emission area G-EA, such that the leakage current can be reduced. Further, referring to Table 1, if the content of p-type dopant doped into the first hole transport layer 321ht of the green emission area G-EA is between the content of p-type dopant doped into the first hole transport layer 321ht of the red emission area R-EA and the content of p-type dopant doped into the first hole transport layer 321ht of the blue emission area B-EA, the leakage current can be significantly reduced.

Therefore, in the display apparatus according to the embodiment of the present disclosure, the content of p-type dopant doped into the first hole transport layer 321ht of the green emission area G-EA can be higher than the content of p-type dopant doped into the first hole transport layer 321ht of the blue emission area B-EA, the content of p-type dopant doped into the first hole transport layer 321ht of the red emission area R-EA can be higher than the content of p-type dopant doped into the first hole transport layer 321ht of the green emission area G-EA, such that the leakage current can be minimized. Further, in the display apparatus according to the embodiment of the present disclosure, efficiency of each emission area R-EA, G-EA and B-EA can be improved.

Further, referring to Table 1, if the p-type dopant contained in the first hole transport layer 321ht of the blue emission area B-EA has a relatively low content, the threshold voltage of the red emission area R-EA and the threshold voltage of the green emission area G-EA can be lower than the threshold voltage of the blue emission area B-EA. For example, in the display apparatus according to the embodiment of the present disclosure, the first hole transport layer 321ht of the blue emission area B-EA can be doped with p-type dopant having a lower content than the first hole transport layer 321ht of the red emission area R-EA and the first hole transport layer 321ht of the green emission area G-EA, such that the driving current can be supplied faster to the light-emitting device 300 of the red emission area R-EA and the light-emitting device 300 of the green emission area G-EA having relatively low efficiency than the light-emitting device 300 of the blue emission area B-EA. Thus, in the display apparatus according to the embodiment of the present disclosure, the deterioration of the quality in the low grayscale image due to an efficiency difference of the light-emitting device 300 in the light emission areas R-EA, G-EA and B-EA of each pixel area PA can be prevented.

An encapsulation structure 400 can be disposed on the light-emitting device 300 of each pixel area PA. The encapsulation structure 400 can prevent damage of the light-emitting device 300 of each pixel area PA due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked on the upper electrode of each pixel area PA. The first encapsulating layer 410, the second encapsulating layer 420 and the third encapsulating layer 430 can include an insulating material. The second encapsulating layer 420 can include a different material from the first encapsulating layer 410 and the third encapsulating layer 430. The second encapsulating layer 420 can include a material having a high fluidity or low viscosity. For example, the first encapsulating layer 410 and the third encapsulating layer 430 can be an inorganic insulating layer made of an inorganic insulating material, and the second encapsulating layer 420 can be an organic insulating layer made of an organic insulating material. Thus, in the display apparatus according to the embodiment of the present disclosure, the damage of the light-emitting device 300 of each pixel area PA due to the external impact and moisture can be effectively prevented. A thickness difference due to the light-emitting device 300 of each pixel area PA can be removed by the second encapsulating layer 420. The second encapsulating layer 420 can have a larger thickness than the first encapsulating layer 410 and the third encapsulating layer 430. For example, an upper surface of the encapsulation structure 400 opposite to the device substrate 100 can be a flat surface or can be made a flat surface.

Accordingly, the display apparatus according to the embodiment of the present disclosure can include the light-emitting unit 320 between the lower electrode 310 and the upper electrode 330 of each emission area R-EA, G-EA and B-EA, wherein the light-emitting unit 320 of each emission area R-EA, G-EA and B-EA can include the hole injection layer 321hi, the first hole transport layer 321ht, the first emission material layer 321em, the p-type charge generating layer 322p, the second hole transport layer 323ht and the second emission material layer 323em, which are spaced apart from the light-emitting unit 320 of adjacent emission area R-EA, G-EA and B-EA on the bank insulating layer 160, wherein the content of p-type dopant in the first hole transport layer 321ht of the blue emission area B-EA can be smaller than the content of p-type dopant in the first hole transport layer 321ht of the red emission area R-EA and the content of p-type dopant in the first hole transport layer 321ht of the green emission area G-EA. Thus, in the display apparatus according to the embodiment of the present disclosure, the leakage current can be minimized, and efficiency of each emission area R-EA, G-EA and B-EA can be improved. Further, in the display apparatus according to the embodiment of the present disclosure, the deterioration of the quality in the low grayscale image due to an efficiency difference of the light-emitting device 300 in each light emission areas R-EA, G-EA and B-EA can be prevented. Therefore, in the display apparatus according to the embodiment of the present disclosure, the quality of the image provided to the user can be improved.

In the display apparatus according to the embodiment of the present disclosure, a voltage applied to the upper electrode 330 of each pixel area PA can be a same as a voltage applied to the upper electrode 330 of adjacent pixel area PA. For example, the upper electrode 330 of each pixel area PA can be electrically connected to the upper electrode 330 of adjacent pixel area PA. The upper electrode 330 of each pixel area PA can include a same material as the upper electrode 330 of adjacent pixel area PA. The upper electrode 330 of each pixel area PA can be formed by a same process as the upper electrode of adjacent pixel area PA. For example, the upper electrode 330 of each pixel area PA can be formed simultaneously with the upper electrode 330 of adjacent pixel area PA. The upper electrode 330 of each pixel area PA can be in direct contact with the upper electrode 330 of adjacent pixel area PA. For example, the upper electrode 330 of each pixel area PA can extend outside of the corresponding pixel area PA. Thus, in the display apparatus according to the embodiment of the present disclosure, a process of forming the upper electrode 330 in each pixel area PA can be simplified. Therefore, in the display apparatus according to the embodiment of the present disclosure, the process efficiency can be improved. Further, in the display apparatus according to the embodiment of the present disclosure, the luminance of the light emitted from the light-emitting device 300 of each pixel area PA can be adjusted by the data signal applied to the driving circuit DC of the corresponding pixel area PA.

Further, in embodiments of the present disclosure, a thickness of the electron transport layer 321et can be different from a thickness of the hole transport layer 321ht of at least one of the emission areas R-EA, G-EA and B-EA, but embodiments of the present disclosure are not limited thereto.

In the display apparatus according to the embodiment of the present disclosure, color filters 500R, 500G and 500B can be disposed on the encapsulation structure 400. The color filters 500R, 500G and 500B can overlap the emission areas R-EA, G-EA and B-EA. Each of the color filters 500R, 500G and 500B can overlap one of the emission areas R-EA, G-EA and B-EA. For example, the color filters 500R, 500G and 500B can include a red color filter 500R overlapping with the red emission area R-EA, a green color filter 500G overlapping with the green emission area G-EA and a blue color filter 500B overlapping with the blue emission area B-EA. The light emitted from the emission area R-EA, G-EA and B-EA of each pixel area PA can be emitted outside through the color filter 500R, 500G and 500B of the corresponding pixel area PA. For example, a size of each color filter 500R, 500G and 500B can be larger than a size of the corresponding emission area R-EA, G-EA and B-EA. Thus, in the display apparatus according to the embodiment of the present disclosure, the color reproducibility of the light emitted from each emission area R-EA, G-EA and B-EA can be effectively improved.

A filter passivation layer 600 can be disposed on the color filter 500R, 500G and 500B of each pixel area PA. The filter passivation layer 600 can prevent damage of the color filters 500R, 500G and 500B due to the external impact and moisture. For example, the color filter 500R, 500G and 500B of each pixel area PA can be completely covered by the filter passivation layer 600. The filter passivation layer 600 can include an insulating material. For example, the filter passivation layer 600 can include at least one of inorganic insulating material and organic insulating material. The filter passivation layer 600 can have a multi-layer structure. For example, the filter passivation layer 600 can have a structure in which an inorganic insulating layer made of inorganic insulating material is formed on an organic insulating layer made of organic insulating material. A thickness difference due to the color filters 500R, 500G and 500B can be removed by the filter passivation layer 600. Thus, in the display apparatus according to the embodiment of the present disclosure, the damage of the color filter 500R, 500G and 500B in each pixel area PA due to the external impact and moisture can be effectively prevented.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor for initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the first hole transport layer 321ht of the blue emission area B-EA can include the p-type dopant having the content lower than the first hole transport layer 321ht of the red emission area R-EA and the first hole transport layer 321ht of the green emission area G-EA. However, in the display apparatus according to another embodiment of the present disclosure, the second hole transport layer 323ht of the blue emission area B-EA can include the p-type dopant having the content lower than the second hole transport layer 323ht of the red emission area R-EA and the second hole transport layer 323ht of the green emission area G-EA. Thus, in the display apparatus according to another embodiment of the present disclosure, the degree of freedom in the configuration of the light-emitting unit 320 in each emission area R-EA, G-EA and B-EA can be improved.

In the display apparatus according to another embodiment of the present disclosure, the first hole transport layer 321ht of the blue emission area B-EA can include the p-type dopant having the content lower than the first hole transport layer 321ht of the red emission area R-EA and the first hole transport layer 321ht of the green emission area G-EA, and the second hole transport layer 323ht of the blue emission area B-EA can include the p-type dopant having the content lower than the second hole transport layer 323ht of the red emission area R-EA and the second hole transport layer 323ht of the green emission area G-EA. For example, in the display apparatus according to another embodiment of the present disclosure, the content of p-type dopant in the first hole transport layer 321ht of the green emission area G-EA can be between the content of p-type dopant in the first hole transport layer 321ht of the blue emission area B-EA and the content of p-type dopant in the first hole transport layer 321ht of the red emission area R-EA, and the content of p-type dopant in the second hole transport layer 323ht of the green emission area G-EA can be between the content of p-type dopant in the second hole transport layer 323ht of the blue emission area B-EA and the content of p-type dopant in the second hole transport layer 323ht of the red emission area R-EA. Thus, in the display apparatus according to another embodiment of the present disclosure, the leakage current can be significantly reduced, and efficiency of the light-emitting device 300 in each emission area R-EA, G-EA and B-EA can be improved. Further, in the display apparatus according to another embodiment of the present disclosure, the deterioration of the quality in the low grayscale image due to an efficiency difference of the light-emitting device 300 in each light emission area R-EA, G-EA and B-EA can be significantly improved.

In the display apparatus according to another embodiment of the present disclosure, the content of p-type dopant in the p-type charge generating layer 322p of each emission area R-EA, G-EA and B-EA can be a same as the content of p-type dopant in the p-type charge generating layer 322p of adjacent emission area R-EA, G-EA and B-EA. For example, in the display apparatus according to another embodiment of the present disclosure, a process of doping the p-type charge generating layer 322p of the blue emission area B-EA with p-type dopant can be performed simultaneously with a process of doping the p-type charge generating layer 322p of the red emission area R-EA with p-type dopant and a process of doping the p-type charge generating layer 322p of the green emission area G-EA with p-type dopant. Thus, in the display apparatus according to another embodiment of the present disclosure, a process of forming the p-type charge generating layer 322p in each emission area R-EA, G-EA and B-EA can be simplified.

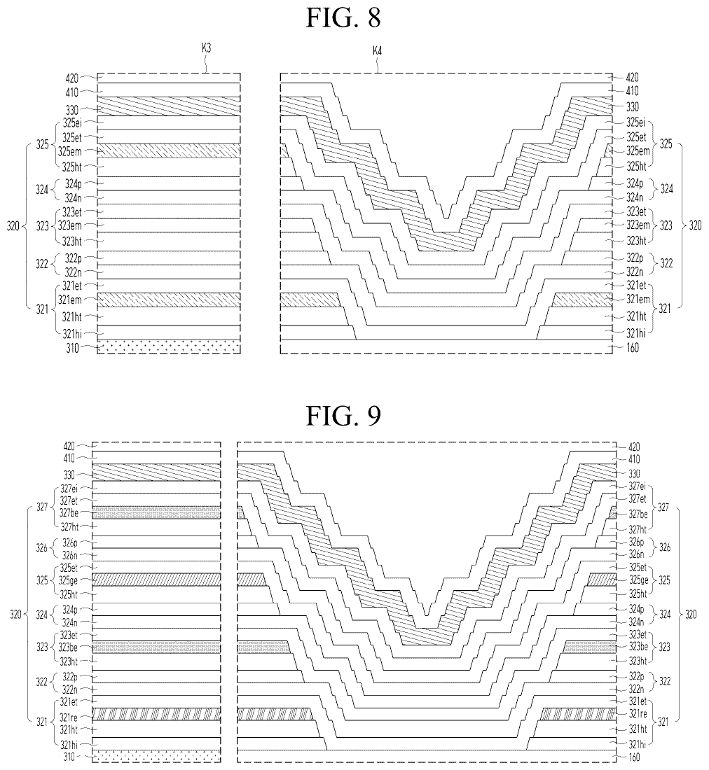

In the display apparatus according to another embodiment of the present disclosure, the p-type charge generating layer 322p of each emission area R-EA, G-EA and B-EA can be formed simultaneously with the p-type charge generating layer 322p of adjacent emission area R-EA, G-EA and B-EA. For example, in the display apparatus according to another embodiment of the present disclosure, the p-type charge generating layer 322p of each emission area R-EA, G-EA and B-EA can be in direct contact with the p-type charge generating layer 322p of adjacent emission area R-EA, G-EA and B-EA, as shown in FIG. 5. Thus, in the display apparatus according to another embodiment of the present disclosure, efficiency in a process can be improved.

In the display apparatus according to another embodiment of the present disclosure, the content of p-type dopant in the first hole transport layer 321ht and the second hole transport layer 323ht of each emission area R-EA, G-EA and B-EA can be a same as the content of p-type dopant in the first hole transport layer 321ht and the second hole transport layer 323ht of adjacent emission area R-EA, G-EA and B-EA, and the content of p-type dopant in the p-type charge generating layer 322p of each emission area R-EA, G-EA and B-EA can be different from the content of p-type dopant in the p-type charge generating layer 322p of adjacent emission area R-EA, G-EA and B-EA. For example, in the display apparatus according to another embodiment of the present disclosure, the first hole transport layer 321ht of each emission area R-EA, G-EA and B-EA can be in direct contact with the first hole transport layer 321ht of adjacent emission area R-EA, G-EA and B-EA, the second hole transport layer 323ht of each emission area R-EA, G-EA and B-EA can be in direct contact with the second hole transport layer 323ht of adjacent emission area R-EA, G-EA and B-EA, and the p-type charge generating layer 322p of each emission area R-EA, G-EA and B-EA can be spaced apart from the p-type charge generating layer 322p of adjacent emission area R-EA, G-EA and B-EA on the bank insulating layer 160, as shown in FIG. 6.

Table 2 shows a threshold voltage difference (A Vth) and a relative leakage current (% Au′v′) between adjacent emission areas R-EA, G-EA and B-EA according to the content of p-type dopant doped into the p-type charge generating layer 322p of the red emission area R-EA, the green emission area G-EA, and the blue emission area B-EA in the display apparatus according to another embodiment of the present disclosure, in which the content of p-type dopant in the first hole transport layer 321ht and the second hole transport layer 323ht of each emission area R-EA, G-EA and B-EA is a same.

TABLE 2

| | | | | ΔVth | ΔVth | Leakage current |
|---|---|---|---|---|---|---|
| | R-EA | G-EA | B-EA | (G-R) | (B-G) | (% Δu'v') |
| Comparative | 4% | 4% | 4% | 0.06 | 0.64 | 100% |
| example 4 | | | | | | |
| Comparative | 3% | 4% | 4% | 0.07 | 0.64 | 100% |
| example 5 | | | | | | |
| Comparative | 4% | 3% | 4% | 0.05 | 0.65 | 99% |
| example 6 | | | | | | |
| Experimental | 4% | 4% | 3% | 0.06 | 0.68 | 90% |
| example 3 | | | | | | |
| Experimental | 5% | 4% | 3% | 0.08 | 0.68 | 91% |
| example 4 | | | | | | |

Referring to Table 2, if the content of p-type dopant doped into the p-type charge generating layer 322p of the blue emission area B-EA is relatively low, a difference in the threshold voltage between the red emission area R-EA and the blue emission area B-EA, and between the green emission area G-EA and the blue emission B-EA can be increased, and the leakage current can be reduced. Thus, in the display apparatus according to another embodiment of the present disclosure, the content of p-type dopant in the first hole transport layer 321ht and the second hole transport layer 323ht of each emission area R-EA, G-EA and B-EA can be the same, and the p-type charge generating layer 322p of the blue emission area B-EA can include a p-type dopant having the content lower than the p-type charge generating layer 322p of the red emission area R-EA and the p-type charge generating layer 322p of the green emission area G-EA. Further, referring to Table 2, if the content of p-type dopant doped into the p-type charge generating layer 322p of the green emission area G-EA is between the content of p-type dopant doped into the p-type charge generating layer 322p of the red emission area R-EA and the content of p-type dopant doped into the p-type charge generating layer 322p of the blue emission area B-EA, the leakage current can be significantly reduced. For example, in the display apparatus according to another embodiment of the present disclosure, the content of p-type dopant doped into the first hole transport layer 321ht and the second hole transport layer 323ht of each emission area R-EA, G-EA and B-EA can be the same, the content of p-type dopant doped into the p-type charge generating layer 322p of the green emission area G-EA can be higher than the content of p-type dopant doped into the p-type charge generating layer 322p of the blue emission area B-EA, the content of p-type dopant doped into the p-type charge generating layer 322p of the red emission area R-EA can be higher than the content of p-type dopant doped into the p-type charge generating layer 322p of the green emission area G-EA, such that the leakage current can be minimized. Therefore, in the display apparatus according to another embodiment of the present disclosure, the leakage current can be reduced or minimized, the deterioration of the quality in the low grayscale image can be prevented, and the degree of freedom in configuration of the light-emitting unit 320 in each emission area R-EA, G-EA and B-EA can be improved.

In the display apparatus according to another embodiment of the present disclosure, the content of p-type dopant doped into the first hole transport layer 321ht of the blue emission area B-EA can be lower than the content of p-type dopant doped into the first hole transport layer 321ht of the red emission area R-EA, and the content of p-type dopant doped into the first hole transport layer 321ht of the green emission area G-EA, and the content of p-type dopant doped into the p-type charge generating layer 322p of the blue emission area B-EA can be lower than the content of p-type dopant doped into the p-type charge generating layer 322p of the red emission area R-EA, and the content of p-type dopant doped into the p-type charge generating layer 322p of the green emission area G-EA.

Table 3 shows a threshold voltage difference (A Vth) and a relative leakage current (% Au′v′) between adjacent emission areas R-EA, G-EA and B-EA according to the content of p-type dopant doped into the first hole transport layer 321ht and the p-type charge generating layer 322p of the red emission area R-EA, the green emission area G-EA, and the blue emission area B-EA in the display apparatus according to another embodiment of the present disclosure.

TABLE 3

| | | | | the p-type | | | | | |
|---|---|---|---|---|---|---|---|---|---|
| | | | | charge | | | | | |
| | the first hole | | | generating | | | | | |
| | transport layer | | | layer | | | | | Leakage |
| | R- | G- | B- | R- | G- | B- | ΔVth | ΔVth | current |
| | EA | EA | EA | EA | EA | EA | (G-R) | (B-G) | (% Δu'v') |
| Comparative | 3% | 3% | 3% | 4% | 4% | 4% | 0.06 | 0.64 | 100% |
| example 7 | | | | | | | | | |
| Experimental | 3% | 3% | 2% | 4% | 4% | 3% | 0.06 | 0.68 | 89% |
| example 5 | | | | | | | | | |
| Experimental | 3% | 3% | 2% | 5% | 4% | 3% | 0.08 | 0.68 | 90% |
| example 6 | | | | | | | | | |
| Experimental | 3% | 2% | 1% | 4% | 4% | 3% | 0.05 | 0.7 | 83% |
| example 7 | | | | | | | | | |
| Experimental | 3% | 2% | 1% | 5% | 4% | 3% | 0.07 | 0.7 | 83% |
| example 8 | | | | | | | | | |

Referring to Table 3, if the content of p-type dopant doped into the first hole transport layer 321ht and the p-type charge generating layer 322p of the blue emission area B-EA is relatively low, a difference in the threshold voltage between the red emission area R-EA and the blue emission area B-EA, and between the green emission area G-EA and the blue emission B-EA can be increased, and the leakage current can be reduced. For example, in the display apparatus according to another embodiment of the present disclosure, the first hole transport layer 321ht of the blue emission area B-EA can include a p-type dopant having the content lower than the first hole transport layer 321ht of the red emission area R-EA and the first hole transport layer 321ht of the green emission area G-EA, and the p-type charge generating layer 322p of the blue emission area B-EA can include a p-type dopant having the content lower than the p-type charge generating layer 322p of the red emission area R-EA and the p-type charge generating layer 322p of the green emission area G-EA. Further, in the display apparatus according to another embodiment of the present disclosure, the content of p-type dopant in the first hole transport layer 321ht of the green emission area G-EA can be lower than the content of p-type dopant in the first hole transport layer 321ht of the red emission area R-EA, and the content of the p-type dopant in the first hole transport layer 321ht of the blue emission area B-EA can be lower than the content of p-type dopant in the first hole transport layer 321ht of the green emission area G-EA. Thus, in the display apparatus according to another embodiment of the present disclosure, the leakage current can be reduced or minimized, the deterioration of the quality in the low grayscale image can be prevented.

Further, referring to Table 3, if the content of p-type dopant doped into the p-type charge generating layer 322p of the blue emission area B-EA is relatively low, a difference between the threshold voltage of the red emission area R-EA and the threshold voltage of the green emission area G-EA can be increased. Thus, in the display apparatus according to another embodiment of the present disclosure, the first hole transport layer 321ht and the p-type charge generating layer 322p of the green emission area G-EA can respectively include a p-type dopant having the content lower than the first hole transport layer 321ht and the p-type charge generating layer 322p of the red emission area R-EA, and the first hole transport layer 321ht and the p-type charge generating layer 322p of the blue emission area B-EA can respectively include a p-type dopant having the content lower than the first hole transport layer 321ht and the p-type charge generating layer 322p of the green emission area G-EA, such that the leakage current can be minimized and a threshold voltage of each emission area R-EA, G-EA and B-EA can be different from a threshold voltage of each emission area R-EA, G-EA and B-EA displaying a different color from the corresponding emission area R-EA, G-EA and B-EA. Therefore, in the display apparatus according to another embodiment of the present disclosure, the deterioration of the quality in the low grayscale image can be effectively prevented.

In the display apparatus according to another embodiment of the present invention, the content of p-type dopant doped into the p-type charge generating layer 322p of each emission area R-EA, G-EA and B-EA may not be significantly different from the content of p-type dopant doped into the first hole transport layer 321ht of the corresponding emission area R-EA, G-EA and B-EA. For example, in the display apparatus according to another embodiment of the present disclosure, the first emission stack 321 and the second emission stack 323 of each emission area R-EA, G-EA and B-EA can have similar resistances. Thus, in the display apparatus according to another embodiment of the present disclosure, the leakage current due to a difference in resistance between the first emission stack 321 and the second emission stack 323 of each emission area R-EA, G-EA and B-EA can be prevented. Therefore, in the display apparatus according to another embodiment of the present disclosure, the leakage current can be efficiently reduced or minimized.

The display apparatus according to the embodiment of the present disclosure is described that the light emitted from the light-emitting device 300 of each pixel area PA can display a different color from the light emitted from the light-emitting device 300 of adjacent pixel area PA. However, in the display apparatus according to another embodiment of the present disclosure, the light emitted from the light-emitting device 300 of each pixel area PA can display a same color as the light emitted from the light-emitting device 300 of adjacent pixel area PA. For example, in the display apparatus according to another embodiment of the present disclosure, the light-emitting device 300 of each pixel area PA can emit white light. For example, in the display apparatus according to another embodiment of the present disclosure, the image including various colors can be realized by the color filters on the pixel areas PA. Thus, in the display apparatus according to another embodiment of the present disclosure, the light-emitting unit 320 of each pixel area PA can have a stacked structure same as the light-emitting unit 320 of adjacent pixel area PA. The light-emitting unit 320 of each pixel area PA can be formed by a same process as the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to another embodiment of the present disclosure, a process of forming the light-emitting unit 320 of each pixel area PA can be simplified.

The display apparatus according to the embodiment of the present disclosure is described that the color filters 500R, 500G and 500B can be disposed on the encapsulation structure 400. However, in the display apparatus according to another embodiment of the present invention, the light emitted from the light-emitting device 300 of each pixel area R-PA, G-PA and B-PA can be emitted outside through the lower electrode 310 of the corresponding pixel area R-PA, G-PA and B-PA and the device substrate 100. For example, in the display apparatus according to another embodiment of the present invention, the color filter 500R, 500G and 500B of each pixel area R-PA, G-PA and B-PA can be disposed between the device passivation layer 140 and the planarization layer 150 of the corresponding pixel area R-PA, G-PA and B-PA, as shown in FIG. 7. For example, in the display apparatus according to another embodiment of the present invention, the color filter 500R, 500G and 500B of each pixel area R-PA, G-PA and B-PA can be disposed between the device passivation layer 140 and the planarization layer 150 of the corresponding pixel area R-PA, G-PA and B-PA, as shown in FIG. 7. The red color filter 500R can be disposed between the device passivation layer 140 and the planarization layer 150 of the red pixel area R-PA, the green color filter 500G can be disposed between the device passivation layer 140 and the planarization layer 150 of the green pixel area G-PA, and the blue color filter 500B can be disposed between the device passivation layer 140 and the planarization layer 150 of the blue pixel area B-PA. The color filters 500R, 500G and 500B can be completely covered by the planarization layer 150. For example, a thickness difference due to the color filters 500R, 500G and 500B can be removed by the planarization layer 150.

A transmittance of the lower electrode 310 can be higher than a transmittance of the upper electrode 330. The upper electrode 330 can have a reflectance higher than the lower electrode 310. For example, in the display apparatus according to another embodiment of the present invention, the lower electrode 310 can be a transparent electrode made of a transparent conductive material, such as ITO and IZO, and the upper electrode 330 can include a metal, such as aluminum (Al) and silver (Ag). But embodiments of the disclosure are not limited thereto. Thus, in the display apparatus according to another embodiment of the present disclosure, the degree of freedom in the configuration of the light-emitting unit 320 in each emission area R-EA, G-EA and B-EA can be improved.

Referring to FIGS. 7 and 8, in the display apparatus according to another embodiment of the present disclosure, the light-emitting unit 320 of each pixel area R-PA, G-PA and B-PA can include a first emission stack 321, a first charge generation layer 322, a second emission stack 323, a second charge generation layer 324 and a third emission stack 325, which are sequentially stacked. The light emitted from one of the first emission stack 321, the second emission stack 323 and the third emission stack 325 in each pixel area R-PA, G-PA and B-PA can display a different color from the light emitted from a remaining emission stack 321, 323 and 325 of the corresponding pixel area PA. At least one of the emission stacks 321, 323 and 325 in each pixel area R-PA, G-PA and B-PA can generate the light displaying a blue color, and at least one of the emission stacks 321, 323 and 325 in each pixel area R-PA, G-PA and B-PA can generate the light displaying a color in a complementary color relationship with a blue color. For example, in the display apparatus according to another embodiment of the present disclosure, a first emission material layer 321em of the first emission stack 321 and a third emission material layer 325em of the third emission stack 325 of each pixel area R-PA, G-PA and B-PA can be a blue emission material layer including a blue fluorescent dopant, and the light generated by a second emission material layer 323em of the second emission stack 323 in each pixel area R-PA, G-PA and B-PA can display yellow color. The second emission material layer 323em can have a multi-layer structure. For example, the second emission material layer 323em can have a stacked structure of a red emission material layer and a green emission material layer, or a stacked structure of a red emission material layer, a yellow-green emission material layer and a green emission material layer. As shown, a K3 region shows various layers that are not spaced apart while a K4 region shows some of the various layers being spaced apart.

The hole injection layer 321hi, the first hole transport layer 321ht and the first emission material layer 321em of the first emission stack 321 in each pixel area R-PA, G-PA and B-PA can be spaced apart from the hole injection layer 321hi, the first hole transport layer 321ht and the first emission material layer 321em of the first emission stack 321 in adjacent pixel area R-PA, G-PA and B-PA on the bank insulating layer 160. The second hole transport layer 323ht and the second emission material layer 323em of the second emission stack 323 in each pixel area R-PA, G-PA and B-PA can be spaced apart from the second hole transport layer 323ht and the second emission material layer 323em of the second emission stack 323 in adjacent pixel area R-PA, G-PA and B-PA on the bank insulating layer 160. The third hole transport layer 325ht and the third emission material layer 325em of the third emission stack 325 in each pixel area R-PA, G-PA and B-PA can be spaced apart from the third hole transport layer 325ht and the third emission material layer 325em of the third emission stack 325 in adjacent pixel area R-PA, G-PA and B-PA on the bank insulating layer 160. The p-type charge generating layer 322p of the first charge generation layer 322 and the p-type charge generating layer 324p of the second charge generation layer 324 in each pixel area R-PA, G-PA and B-PA can be spaced apart from the p-type charge generating layer 322p of the first charge generation layer 322 and the p-type charge generating layer 324p of the second charge generation layer 324 in adjacent pixel area R-PA, G-PA and B-PA on the bank insulating layer 160. Therefore, in the display apparatus according to another embodiment of the present disclosure, the degree of freedom in the configuration of the light-emitting unit 320 in each pixel area R-PA, G-PA and B-PA can be improved.

As shown in FIG. 9, in the display apparatus according to another embodiment of the present disclosure, the light-emitting unit 320 disposed between the lower electrode 310 and the upper electrode 330 in each pixel area can have a stacked structure of an emission stack 321 including a red emission material layer 321re, an emission stack 325 including a green emission material layer 325ge and an emission stack 323 and 327 including a blue emission material layer 323be and 327be. For example, in the display apparatus according to another embodiment of the present disclosure, the light-emitting unit 320 of each pixel area can include the first emission stack 321, the first charge generation layer 322, the second emission stack 323, the second charge generation layer 324, the third emission stack 325, the third charge generation layer 326 and the fourth emission stack 327, wherein the first emission stack 321 can include the red emission material layer 321re, wherein the third emission stack 325 can include the green emission material layer 325ge, and each of the second emission stack 323 and the fourth emission stack 327 can include the blue emission material layer 323be and 327be. Each of the first charge generation layer 322, the second charge generation layer 324 and the third charge generation layer 326 can have a stacked structure of the n-type charge generating layer 322n, 324n and 326n, and the p-type charge generating layer 322p, 324p and 326p. In embodiments of the present disclosure, one or more of the p-type charge generating layer 322p, 324p and 326p can have a thickness that is different from a thickness of the hole injection layer 321hi, respectively. For example, the one or more of the p-type charge generating layer 322p, 324p and 326p can have the thickness that is greater than the thickness of the hole injection layer 321hi, but embodiments of the present disclosure are not limited thereto.

The hole injection layer 321hi, the first hole transport layer 321ht and the red emission material layer 321re of each pixel area can be spaced apart from the hole injection layer 321hi, the first hole transport layer 321ht and the red emission material layer 321re of adjacent pixel area on the bank insulating layer 160. The p-type charge generating layer 322p of the first charge generation layer 322 in each pixel area can be spaced apart from the p-type charge generating layer 322p of the first charge generation layer 322 in adjacent pixel area on the bank insulating layer 160. The second hole transport layer 323ht and the blue emission material layer 323be of the second emission stack 323 in each pixel area can be spaced apart from the second hole transport layer 323ht and the blue emission material layer 323be of the second emission stack 323 in adjacent pixel area on the bank insulating layer 160. The p-type charge generating layer 324p of the second charge generation layer 324 in each pixel area can be spaced apart from the p-type charge generating layer 324p of the second charge generation layer 324 in adjacent pixel area on the bank insulating layer 160. The third hole transport layer 325ht and the green emission material layer 325re of each pixel area can be spaced apart from the third hole transport layer 325ht and the green emission material layer 325re of adjacent pixel area on the bank insulating layer 160. The p-type charge generating layer 326p of the third charge generation layer 326 in each pixel area can be spaced apart from the p-type charge generating layer 326p of the third charge generation layer 326 in adjacent pixel area on the bank insulating layer 160. The fourth hole transport layer 327ht and the blue emission material layer 327be of the fourth emission stack 327 in each pixel area can be spaced apart from the fourth hole transport layer 327ht and the blue emission material layer 327be of the fourth emission stack 327 in adjacent pixel area on the bank insulating layer 160. The first electron transport layer 321et and the n-type charge generating layer 322n of the first charge generation layer 322 in each pixel area can be in direct contact with the first electron transport layer 321et and the n-type charge generating layer 322n of the first charge generation layer 322 in adjacent pixel area. The second electron transport layer 323et and the n-type charge generating layer 324n of the second charge generation layer 324 in each pixel area can be in direct contact with the second electron transport layer 323et and the n-type charge generating layer 324n of the second charge generation layer 324 in adjacent pixel area. The third electron transport layer 325et and the n-type charge generating layer 326n of the third charge generation layer 326 in each pixel area can be in direct contact with the third electron transport layer 325et and the n-type charge generating layer 326n of the third charge generation layer 326 in adjacent pixel area. The fourth electron transport layer 327et and the electron injection layer 327ei in each pixel area can be in direct contact with the fourth electron transport layer 327et and the electron injection layer 327ei in adjacent pixel area. Thus, in the display apparatus according to another embodiment of the present disclosure, the leakage current can be reduced or minimized, and efficiency of the light-emitting device on each pixel area can be improved, regardless of the configuration of the light-emitting unit 320 in each pixel area.

In an example, referring to FIGS. 4, 5, 6, 8 and 9, in the K1 region or the K3 region, various layers of the light-emitting unit 320 are continuous and not spaced apart, so that the various layers are sequentially stacked one upon the other. On the other hand, in the K2 region or the K4 region, among the various layers, some of the layers of the light-emitting unit 320 are spaced apart while other layers of the light-emitting unit 320 are not spaced apart over the bank insulating layer 160. When a layer is spaced apart in the K2 or K4 region, one or more continuous layers can be interposed between portions of the layer that are spaced apart. For example, in the K2 or K4 region, the first hole transport layer 321ht can be spaced apart to be discontinuous. Between the portions of the first hole transport layer 321ht that are spaced apart, portions of one or more of the first electron transport layer 321et, the n-type charge generating layer 322n, and the second electron transport layer 323et can be located therein.

In an example, when one or more of the first electron transport layer 321et, the n-type charge generating layer 322n, and the second electron transport layer 323et are located between the portions of the first hole transport layer 321ht that are spaced apart (see K2 region of FIG. 4), the one or more of the first electron transport layer 321et, the n-type charge generating layer 322n, and the second electron transport layer 323et can each have at least one stepped portion and a planar portion. The planar portions of the first electron transport layer 321et, the n-type charge generating layer 322n, and the second electron transport layer 323et are provided on a planar part of the bank insulating layer 160, while the stepped portions of the first electron transport layer 321et, the n-type charge generating layer 322n, and the second electron transport layer 323et are provide on a disconnected edge of the first hole transport layer 321ht. The planar portions and the stepped portions of the first electron transport layer 321et, the n-type charge generating layer 322n, and the second electron transport layer 323et are connected to each other, respectively. In various embodiments of the present disclosure, the stepped portions can be located higher than the planar portions. However, embodiments of the present disclosure are not limited thereto.

In an example, referring to FIGS. 4, 5, 6, 8 and 9, in the K2 region or the K4 region, although stepped portions can be located higher than the planar portions, in other embodiments of the present disclosure, the stepped portions can be located at a same height, or can be lower than the planar portion. For example, a filler material that is non-conductive can be located between the portions of the first hole transport layer 321ht that are spaced apart, and have a thickness that is equal to or greater than the first hole transport layer 321ht. Alternately, the planar portions of one or more of the first electron transport layer 321et, the n-type charge generating layer 322n, and the second electron transport layer 323et can have a thickness that is greater than those of the stepped portions so as to compensate for a height difference of disconnected portions of the first hole transport layer 321ht that are spaced apart, for example.

In an example, referring to FIGS. 4, 5, 6, 8 and 9, in the K2 region or the K4 region, as some of the various layers of the light-emitting unit 320 have portions that are spaced apart, while other layers of the light-emitting unit 320 are not spaced apart, the other layers of the light-emitting unit 320 are not spaced apart are stacked in the planar portion of the bank insulating layer 160 so that a recess is formed thereon. In various embodiments of the present disclosure a portion of the second encapsulation layer 420 can be located in the recess thus formed. However, embodiments of the present disclosure are not limited thereto. For example, the filler is used or when the planar portions of one or more of the first electron transport layer 321et, the n-type charge generating layer 322n, and the second electron transport layer 323et have a thickness that is greater than those of the stepped portions, then a top surface of the first encapsulation layer 410 can be planar at the K2 region or can extend upward to protrude into the second encapsulation layer 420. The recess or protrusion in the K2 region or the K4 region can be uneven, and can have multiple stepped portions.

In an example, referring to FIGS. 4, 5, 6, 8 and 9, in the K2 region or the K4 region, the planar portions of one or more of the first electron transport layer 321et, the n-type charge generating layer 322n, and the second electron transport layer 323et can have lengths that are different from each other. For example, the planar portion of the first electron transport layer 321et can be longer than the planar portion of the second electrode transport layer 323et. However, embodiments of the present disclosure are not limited thereto, and the lengths thereof can be about the same in other embodiments of the present disclosure.

Accordingly, the display apparatus according to one or more embodiments of the present disclosure can comprise the light-emitting unit disposed between the lower electrode and the upper electrode in each pixel area, wherein the light-emitting unit can include the charge generation layer and at least one hole transport layer, wherein the hole transport layer and/or the charge generation layer of the first pixel area displaying a blue color can be spaced apart from the hole transport layer and/or the charge generation layer of the second pixel area displaying a different color from the first pixel area, and wherein the hole transport layer and/or the charge generation layer of the first pixel area can have a p-type dopant having the content lower than the hole transport layer and/or the charge generation layer of the second pixel area. Thus, in the display apparatus according to the embodiments of the present disclosure, the leakage current can be minimized. Therefore, in the display apparatus according to the various embodiments of the present disclosure, efficiency of each pixel area can be improved. Further, in the display apparatus according to the embodiments of the present disclosure, power consumption can be reduced by low power driving and improved display apparatuses can be provided.

What is claimed is:

1. A display apparatus comprising:
a device substrate including a first pixel area and a second pixel area, the first pixel area for displaying a blue color, and the second pixel area for displaying a different color from the blue color displayed by the first pixel area;
a first light-emitting device on the first pixel area of the device substrate, the first light-emitting device having a stacked structure of a first lower electrode, a first lower hole transport layer, a first lower emission material layer, a first charge generation layer, a first upper emission material layer and a first upper electrode; and
a second light-emitting device on the second pixel area of the device substrate, the second light-emitting device having a stacked structure of a second lower electrode, a second lower hole transport layer, a second lower emission material layer, a second charge generation layer, a second upper emission material layer and a second upper electrode,
wherein the second lower hole transport layer is spaced apart from the first lower hole transport layer between the first pixel area and the second pixel area, and
wherein a content of a p-type dopant in the first lower hole transport layer is smaller than a content of the p-type dopant in the second lower hole transport layer.

2. The display apparatus according to claim 1, wherein the p-type dopant in the second lower hole transport layer includes a same material as the p-type dopant in the first lower hole transport layer.

3. The display apparatus according to claim 1, wherein the first light-emitting device includes a first upper hole transport layer between the first charge generation layer and the first upper emission material layer,
wherein the second light-emitting device includes a second upper hole transport layer between the second charge generation layer and the second upper emission material layer, and
wherein the second upper hole transport layer is spaced apart from the first upper hole transport layer.

4. The display apparatus according to claim 3, wherein a content of a p-type dopant in the first upper hole transport layer is smaller than a content of a p-type dopant in the second upper hole transport layer.

5. The display apparatus according to claim 1, further comprising a third light-emitting device on a third pixel area of the device substrate,
wherein the third light-emitting device includes a stacked structure of a third lower electrode, a third lower hole transport layer, a third lower emission material layer, a third charge generation layer, a third upper emission material layer and a third upper electrode,
wherein the third pixel area displays a different color from at least one of the first pixel area and the second pixel area,
wherein the third lower hole transport layer is spaced apart from the first lower hole transport layer and the second lower hole transport layer, and
wherein a content of a p-type dopant in the third lower hole transport layer is greater than the content of the p-type dopant in the first lower hole transport layer.

6. The display apparatus according to claim 5, wherein the second pixel area displays a green color, and the third pixel area displays a red color, and
wherein the content of the p-type dopant in the third lower hole transport layer is greater than the content of the p-type dopant in the second lower hole transport layer.

7. The display apparatus according to claim 1, wherein the second lower emission material layer is spaced apart from the first lower emission material layer,
wherein the second upper emission material layer is spaced apart from the first upper emission material layer,
wherein light emitted from the first upper emission material layer displays a same color as light emitted from the first lower emission material layer, and
wherein light emitted from the second upper emission material layer displays a same color as light emitted from the second lower emission material layer.

8. The display apparatus according to claim 1, wherein each of the first charge generation layer and the second charge generation layer has a stacked structure of an n-type charge generating layer and a p-type charge generating layer, and
wherein the p-type charge generating layer of the second charge generation layer is spaced apart from the p-type charge generating layer of the first charge generation layer.

9. A display apparatus comprising:
a first lower electrode on a first emission area of a device substrate;
a second lower electrode on a second emission area of the device substrate;
a light-emitting unit on the first lower electrode and the second lower electrode, the light-emitting unit having a stacked structure of a first emission material layer, a charge generation layer and a second emission material; and
an upper electrode on the light-emitting unit and overlapping with the first emission area and the second emission area,
wherein the charge generation layer of the light-emitting unit has a stacked structure of an n-type charge generating layer and a p-type charge generating layer,
wherein the p-type charge generating layer overlaps with the second emission area and is spaced apart from the p-type charge generating layer that overlaps with the first emission area, and
wherein a content of a p-type dopant in the p-type charge generating layer on the second emission area is different from a content of a p-type dopant in the p-type charge generating layer on the first emission area.

10. The display apparatus according to claim 9, wherein the p-type dopant in the p-type charge generating layer on the second emission area includes a same material as the p-type dopant in the p-type charge generating layer on the first emission area.

11. The display apparatus according to claim 9, wherein the light-emitting unit includes an upper hole transport layer between the charge generation layer and the second emission material layer,
wherein the upper hole transport layer overlaps with the second emission area and is spaced apart from the upper hole transport layer that overlaps with the first emission area, and
wherein a content of a p-type dopant in the upper hole transport layer on the second emission area is different from a content of a p-type dopant in the upper hole transport layer on the first emission area.

12. The display apparatus according to claim 11, wherein the content of the p-type dopant in the p-type charge generating layer on the first emission area is smaller than the content of the p-type dopant in the p-type charge generating layer on the second emission area, and
wherein the content of the p-type dopant in the upper hole transport layer on the first emission area is smaller than the content of the p-type dopant in the upper hole transport layer on the second emission area.

13. The display apparatus according to claim 9, further comprising a third lower electrode on a third emission area of the device substrate,
wherein the light-emitting unit and the upper electrode extend onto the third lower electrode of the third emission area,
wherein the p-type charge generating layer overlaps with the third emission area is spaced apart from the p-type charge generating layer that overlaps with the first emission area and the p-type charge generating layer that overlaps with the second emission area, and
wherein a content of a p-type dopant in the p-type charge generating layer on the third emission area is different from the content of the p-type dopant in the p-type charge generating layer on the first emission area.

14. The display apparatus according to claim 13, wherein the content of the p-type dopant in the p-type charge generating layer on the third emission area is different from the content of the p-type dopant in the p-type charge generating layer on the second emission area.

15. The display apparatus according to claim 9, further comprising:
a first color filter between the first emission area of the device substrate and the first lower electrode; and
a second color filter between the second emission area of the device substrate and the second lower electrode,
wherein each of the first emission material layer and the second emission material layer in the light-emitting unit overlaps the first emission area and the second emission area, and
wherein the second color filter includes a different material from the first color filter.

16. The display apparatus according to claim 9, wherein the light-emitting unit further includes an electron transport layer on the first emission area and the second emission area, and disposed between the p-type charge generating layer that overlaps with the second emission area and the p-type charge generating layer that overlaps with the first emission area.

17. The display apparatus according to claim 16, wherein the electron transport layer includes a stepped portion and a planar portion, and
wherein the stepped portion is on the first emission area and the second emission area, and the planar portion is disposed between the p-type charge generating layer that overlaps with the second emission area and the p-type charge generating layer that overlaps with the first emission area.

18. A display apparatus comprising:
a device substrate including a first pixel area for displaying a blue color and a second pixel area for displaying a non-blue color;
a first light-emitting device on the first pixel area, and having a first lower electrode, a first lower hole transport layer, a first lower emission material layer, a first charge generation layer, a first upper emission material layer and a first upper electrode; and
a second light-emitting device on the second pixel area, and having a second lower electrode, a second lower hole transport layer, a second lower emission material layer, a second charge generation layer, a second upper emission material layer and a second upper electrode,
wherein the second lower hole transport layer is spaced apart from the first lower hole transport layer between the first pixel area and the second pixel area, and
wherein a content of a p-type dopant in the first lower hole transport layer or the first charge generation layer is different than a content of a p-type dopant in the second lower hole transport layer or the second charge generation layer.

19. The display device according to claim 18, wherein the content of the p-type dopant in the first lower hole transport layer is smaller than the content of the p-type dopant in the second lower hole transport layer.

20. The display device according to claim 18, wherein the content of the p-type dopant in the first charge generation layer is smaller than the content of the p-type dopant in the second charge generation layer.
